(19) United States
(12) Patent Application Publication
(10) Pub. No.: US 2012/0262861 A1
(43) Pub. Date: Oct. 18, 2012

(54) Rack with a Power Distribution Unit

(75) Inventor: Yu-Ming Lin, New Taipei City (TW)

(73) Assignee: WISTRON CORPORATION, New Taipei City (TW)

(21) Appl. No.: 13/413,891

(22) Filed: Mar. 7, 2012

(30) Foreign Application Priority Data
Apr. 12, 2011 (TW) 100112647

(51) Int. Cl. H05K 7/00

(52) U.S. Cl. 361/679.02

(57) ABSTRACT

A rack is adapted for storing a plurality of servers, and includes a rack body and a power distribution unit. The rack body includes a top portion, a bottom portion and a plurality of supporting rods. The supporting rods connect vertically the top portion to the bottom portion. One of the supporting rods is formed with a receiving groove. The servers are placed among the supporting rods. The power distribution unit includes a plurality of socket units retained in the receiving groove.

### CROSS-REFERENCE TO RELATED APPLICATION

This application claims priority of Taiwanese Application No. 100112647, filed on Apr. 12, 2011, the disclosure of which is incorporated herein by reference.

### BACKGROUND OF THE INVENTION

1. Field of the Invention

The invention relates to a rack, more particularly to a rack for storing a plurality of servers.

2. Description of the Related Art

As shown in FIGS. 1 and 2, a conventional rack 1 for storing a plurality of servers 100 includes a rack body 11, at least one power distribution unit (PDU) 12, and a power support rack 13. The rack body 11 includes a plurality of upright supporting rods 111, and the servers 100 are secured between the supporting rods 111 and vertically aligned with each other in the rack body 11. The PDU 12 is placed at a side of the rack body 11 via being secured on the power support rack 13 which is secured between an adjacent pair of the supporting rods 111.

The PDU 12 includes two case members 121 and 122 that are coupled to each other to form an elongated hollow case, and a plurality of socket units 123 that are disposed between and exposed from the case members 121 and 122. The case member 122 of the PDU 12 is locked on the power support rack 13. Each of the servers 100 includes a back side 101 and a power cable 102 that is connected to the back side 101 of the server 100. The socket unit 123 is for being connected electrically to the power cable 102.

When the servers 100 are stored in the conventional rack 1, the PDU 12 and the power cables 102 of the servers 100 are at two different sides of the rack 1. For consideration of routing the power cable 102, a predetermined amount of space must be reserved between each adjacent pair of servers 100 for passage of the power cables 102 therethrough toward the socket unit 123. The reserved spaces, however, reduce the number of the servers 100 that can be stored in the conventional rack 1. Moreover, when a plurality of the conventional racks 1 are placed in a central control room, space outside each rack body 11 adjacent to the back sides 101 of the servers 100 and the PDU 12 has to be reserved for the sake of maintenance for each rack 1. This configuration results in an inefficient space arrangement inside each rock body 11 and in the central control room.

### SUMMARY OF THE INVENTION

Therefore, an object of the present invention is to provide a rack with a structure that is relatively simple.

Another object of the present invention is to provide a rack that can achieve a more efficient space allocation both inside and outside the rack.

Accordingly, a rack of the present invention is adapted for storing a plurality of servers. The rack comprises a rack body and a power distribution unit. The rack body includes a top portion, a bottom portion and a plurality of supporting rods. The supporting rods connect vertically the top portion to the bottom portion. One of the supporting rods is formed with a receiving groove. The servers are placed among the supporting rods. The power distribution unit includes a plurality of socket units retained in the receiving groove of the supporting rods.

This invention integrates the power distribution unit into the supporting rod formed with the receiving groove so as to omit some elements of the power distribution unit that are required in the conventional racks, thereby reducing manufacturing costs.

Moreover, each of the servers includes a back side and a power cable connected to the back side. The one of the supporting rods cooperates with another one of the supporting rods to form an opening side. The back sides of the servers face the opening side.

Due to the facts that when the servers are stored in the rack, the back sides of the servers are facing the opening side, and that the one of the supporting rods formed with the receiving groove is the one that cooperates with another one of the supporting rods to form the opening side, a power cable that interconnects one of the servers and the power distribution unit would be relatively short and would not be required to extend between an adjacent pair of servers, thereby increasing the number of servers that can be stored in the rack.

The top portion has a plurality of first corner ends. The bottom portion has a plurality of second corner ends that correspond respectively in position to the first corner ends. Each of the supporting rods interconnects a respective one of the first corner ends and a corresponding one of the second corner ends. The rack body has a substantially cubic frame structure.

In this invention, the power distribution unit is located at a corner of the rack body, and the power distribution unit and the opening side are located at the same side of the rack body. Compare to the abovementioned conventional racks, the configuration of this invention eliminates the requirement of reserved space inside the rack body and in the central control room, thereby achieving a more efficient space allocation inside the rack body as well as inside the central control room.

The power distribution unit further includes a covering plate. The covering plate is coupled to the one of the supporting rods, covers the receiving groove, and is formed with a plurality of openings for exposing the socket units respectively.

The supporting rod formed with the receiving groove includes a rod body that has a substantially U-shaped cross section and that defines the receiving groove therein, and a plurality of rib structures that are disposed in the receiving groove. The covering plate is secured onto the rib structures. The supporting rod may be configured as an aluminum extruded pipe.

### BRIEF DESCRIPTION OF THE DRAWINGS

Other features and advantages of the present invention will become apparent in the following detailed description of the embodiment with reference to the accompanying drawings, of which:

FIG. 1 is a perspective view of a conventional rack;

FIG. 2 is an exploded perspective view of a power distribution unit of the conventional rack;

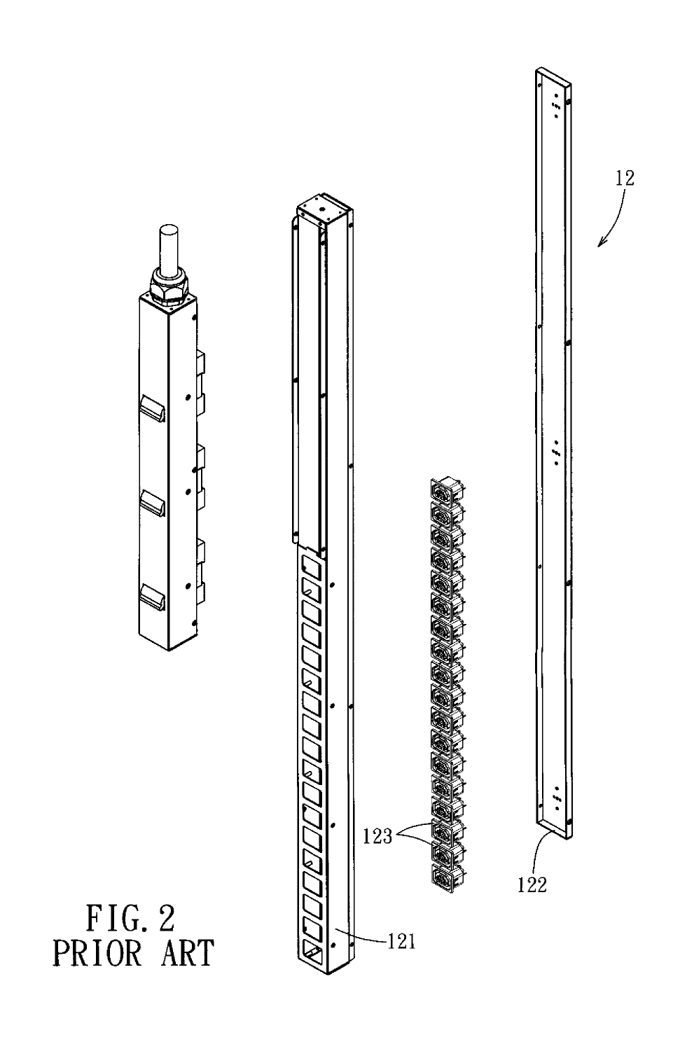

FIG. 3 is a perspective view of an embodiment of a rack according to the invention;

FIG. 4 is a fragmentary partly exploded perspective view illustrating a power distribution unit of the embodiment being assembled onto a supporting rod;

FIG. 5 is a fragmentary exploded perspective view illustrating the power distribution unit and the supporting rod of the embodiment; and

FIG. 6 is a fragmentary sectional view of the embodiment.

### DETAILED DESCRIPTION OF THE EMBODIMENT

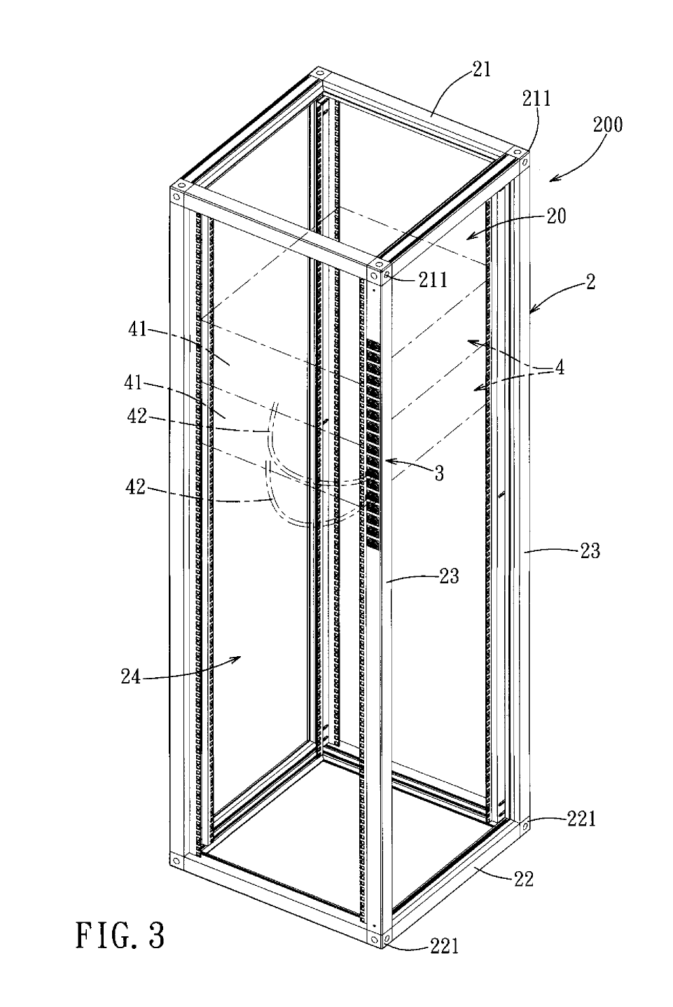

As shown in FIG. 3, an embodiment of a rack 200 according to the present invention includes a rack body 2 and a power distribution unit (PDU) 3.

The rack body 2 includes a top portion 21, a bottom portion 22 and a plurality of supporting rods 23 that connect vertically the top portion 21 to the bottom portion 22, and that cooperate with the top and bottom portions 21, 22 to define a rack space 20 for storing a plurality of servers 4 therein. The servers 4 are secured among the supporting rods 23 and are vertically aligned with each other. Each of the servers 4 includes a back side 41 and a power cable 42 that is connected to the back side 41.

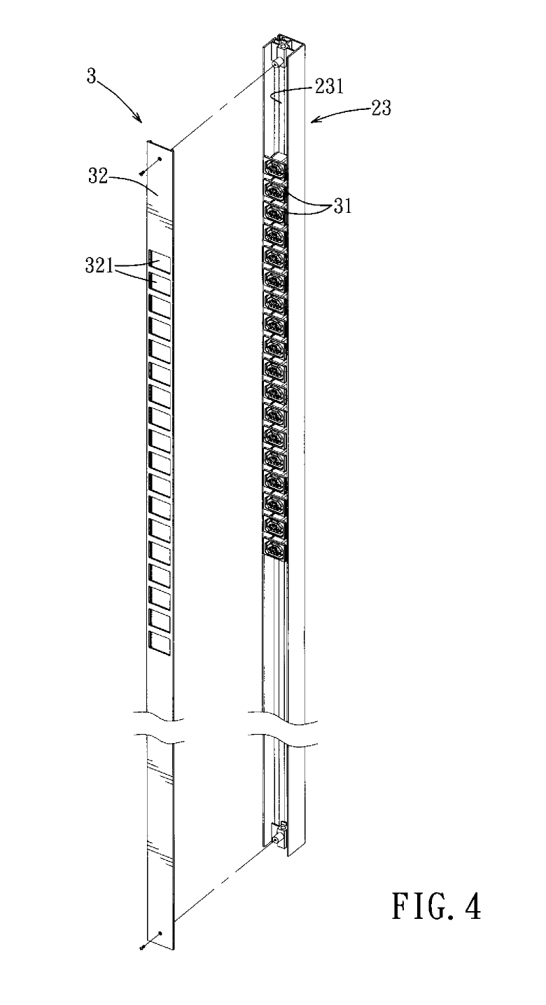

Further referring to FIG. 4, one of the supporting rods 23 is formed with a receiving groove 231 that extends in the vertical direction, and the PDU 3 is coupled to the supporting rod 23 formed with the receiving groove 231. Specifically, the PDU 3 includes a plurality of socket units 31 that are retained in the receiving groove 231, and that are for being plugged by the power cables 42 of the servers 4. Certainly, each of the socket units 31 is connected to an electrical wire, and the electrical wires extend out of the supporting rod 23 to connect electrically to a power source.

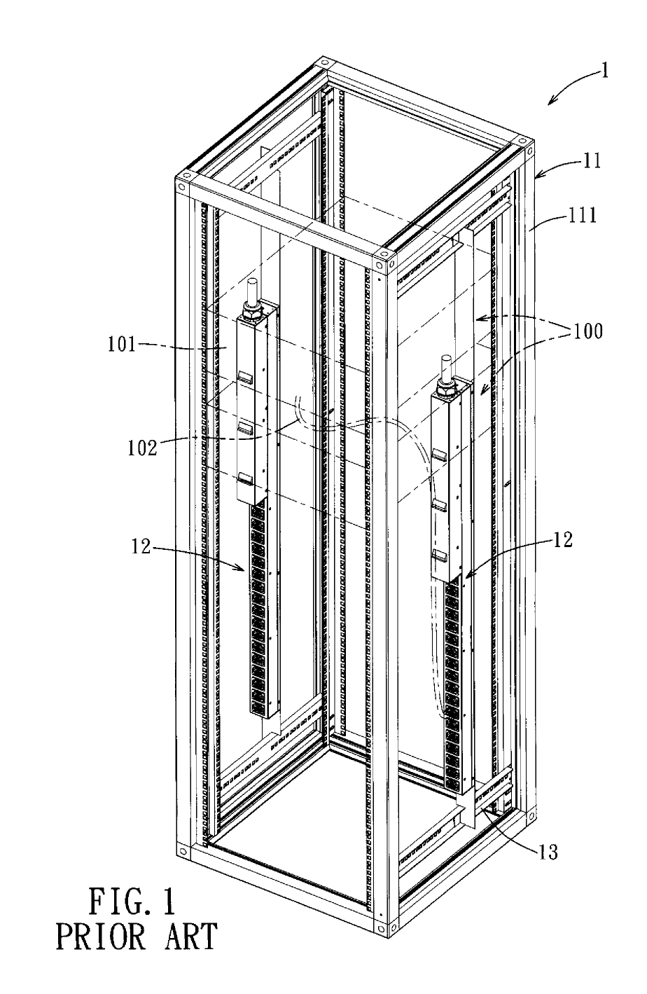

As mentioned above, one advantage of the present invention is, by integrating PDU 13 into the one of the supporting rods 23, the power support rack 13 and some elements of the PDU 12 that are illustrated in the conventional rack 1 (see FIG. 1) can be omitted, thereby reducing manufacturing cost of the rack 200 of this invention.

The number of the supporting rod 23 formed with the receiving groove 231 may be multiple. In other words, the rack 200 may include a plurality of PDUs 3 integrated respectively into a plurality of the supporting rods 23.

Additionally, an adjacent pair of the supporting rods 23 cooperate with each other to form an opening side 24 that communicates spatially with the rack space 20. When the servers 4 are stored in the rack body 2, the back sides 41 of the servers 4 face the opening side 24 of the rack body 2. In this embodiment, the supporting rod 23 that is formed with the receiving groove 231 is one of the adjacent pair of the supporting rods 23 that form the opening side 24.

Another advantage of the present invention is that, since the back sides 41 of the servers 4 are facing the opening side 24 when the servers 4 are stored in the rack body 2, and since the PDU 3 is retained in one of the supporting rods 23 that form the opening side 24, each power cable 42 can connect electrically a corresponding one of the servers 4 to the PDU 3 in a relatively short length without extending between an adjacent pair of servers 4, thereby eliminating the requirement to reserve space between the adjacent pair of the servers 4, and increasing the number of servers 4 that can be stored in the rack 2.

Specifically, the rack body 2 in this embodiment has a substantially cubical frame structure. The top and bottom portions 21, 22 are configured as rectangular frames, and may be manufactured by assembling a plurality of rod members. The top portion 21 has a plurality of first corner ends 211, and the bottom portion 22 has a plurality of second corner ends 221 that corresponds respectively in position to the first corner ends 211. Each of the supporting rods 23 interconnects a respective one of the first corner ends 211 of the top portion 21 and a corresponding one of the second corner ends 221 of the bottom portion 22. Therefore, the one of the supporting rod 23 that is formed with the receiving groove 231 is also disposed between one of the first corner ends 211 and a corresponding one of the second corner ends 221. In other words, the PDU 3 is located at a corner of the cubic frame structure of the rack body 2, and is located at the same side of the rack body 2 as with the opening side 24. This configuration eliminates the requirement to reserve space around the rack body 2 for maintenance when multiple racks 200 are aligned in a central control room, thereby achieving a more efficient space allocation in the central control room.

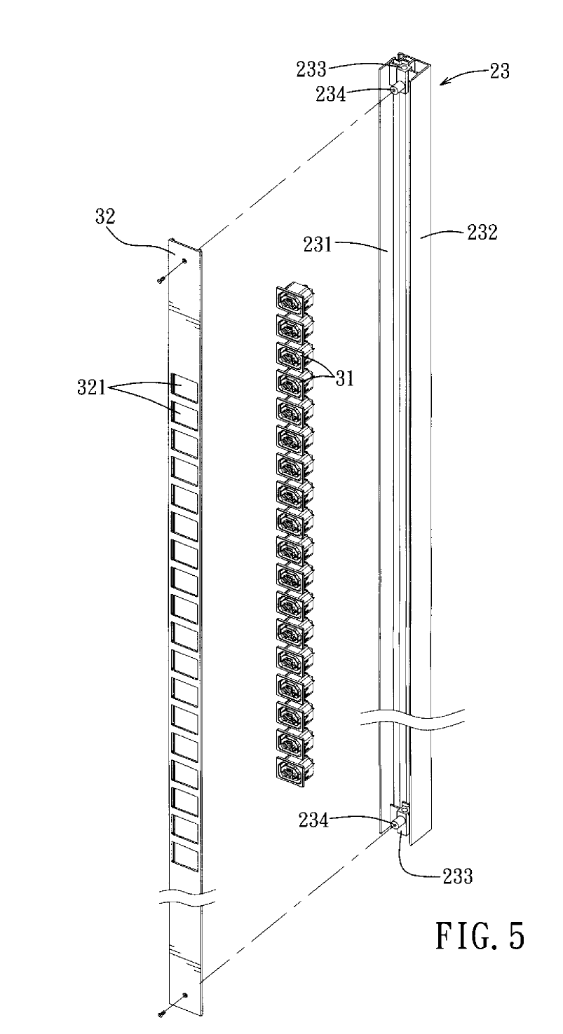

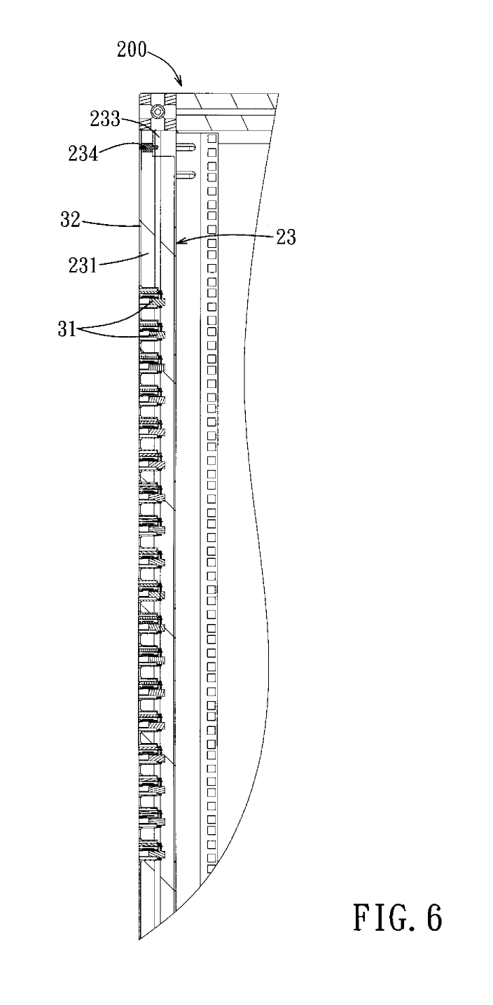

Further referring to FIGS. 5 and 6, the PDU 3 includes an elongated covering plate 32 that is coupled to the one of the supporting rods 23, that covers the receiving groove 231, and that is formed with a plurality of openings 321 for exposing the socket units 31 respectively.

Furthermore, the supporting rod 23 formed with the receiving groove 231 includes a rod body 232 that has a substantially U-shaped cross section and that defines the receiving groove 231 therein, and a plurality of rib structures 233 that are disposed in the receiving groove 231 of the rod body 232 and that are adjacent respectively to opposite ends of the rod body 232. The rib structures 233 are formed respectively with screw apertures 234 such that the covering plate 32 can be secured to the rib structures 233 by screws. Specifically, the one of the supporting rods 23 may be configured as an aluminum extruded pipe.

To sum up, the present invention integrates the PDU 3 into at least one of the supporting rods 23 of the rack body 2, thereby resulting in reduction of the manufacturing cost. Additionally, compared to the conventional rack 1 illustrated in FIG. 1, the improved configuration of the PDU 3 can achieve a more efficient space allocation of the rack space 20 as well as the space inside the central control room.

While the present invention has been described in connection with what is considered the most practical embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A rack adapted for storing a plurality of servers, said rack comprising:
a rack body including
a top portion,
a bottom portion, and
a plurality of supporting rods that connect vertically said top portion to said bottom portion, one of said supporting rods being formed with a receiving groove, the servers to be placed among said supporting rods; and
a power distribution unit including a plurality of socket units that are retained in said receiving groove of said supporting rod.

2. The rack as claimed in claim 1, each of the servers including a back side and a power cable that is connected to the back side, wherein said one of said supporting rods formed with said receiving groove cooperates with another one of said supporting rods to form an opening side, the back sides of the servers to be disposed to face said opening side.

3. The rack as claimed in claim 2, wherein said top portion has a plurality of first corner ends, said bottom portion having a plurality of second corner ends that correspond respectively in position to said first corner ends, each of said supporting rods interconnecting a respective one of said first corner ends and a corresponding one of said second corner ends.

4. The rack as claimed in claim 1, wherein said power distribution unit further includes a cove ring plate that is coupled to said one of said supporting rods, that covers said receiving groove, and that is formed with a plurality of openings for exposing said socket units respectively.

5. The rack as claimed in claim 1, wherein:
said one of said supporting rods formed with said receiving groove includes
a rod body that has a substantially U-shaped cross section and that defines said receiving groove therein, and
a plurality of rib structures that are disposed in said receiving groove; and
said covering plate is secured onto said rib structures.

6. The rack as claimed in claim 5, wherein said one of said supporting rods is configured as an aluminum extruded pipe.
